(19) United States
(12) Patent Application Publication
(10) Pub. No.: US 2019/0044535 A1
(43) Pub. Date: Feb. 7, 2019

(54) SYSTEMS AND METHODS FOR COMPRESSING PARAMETERS OF LEARNED PARAMETER SYSTEMS

(71) Applicant: Intel Corporation, Santa Clara, CA (US)

(72) Inventor: Jahanzeb Ahmad, Chesham (GB)

(21) Appl. No.: 16/146,652

(22) Filed: Sep. 28, 2018

(51) Int. Cl. H03M 7/46; G06N 3/08; G06N 3/04; G06F 9/30

(52) U.S. Cl. CPC H03M 7/46; G06N 3/08; G06F 9/30149; G06F 9/3001; G06N 3/04

(57) ABSTRACT

Systems and methods of the present disclosure may improve operation efficiency of learned parameter systems implemented via integrated circuits. A method for implementing compressed parameters, via a processor coupled to the integrated circuit, may include receiving a sequence of parameters. The method may also include comparing a length of a run of the sequence to a run-length threshold, where the run includes a consecutive portion of parameters of the sequence. The method may further include, in response to the run being greater than or equal to the run-length threshold, compressing the parameters of the run using run-length encoding. Furthermore, the method may include storing the parameters of the run in a compressed form into memory associated with the integrated circuit such that the integrated circuit may retrieve the parameters of the run in the compressed form, decode the parameters, and use the parameters in the learned parameter system.

### BACKGROUND

The present disclosure relates generally to learned parameter systems, such as Deep Neural Networks (DNN). More particularly, the present disclosure relates to improving the efficiency of implementing learned parameter systems onto an integrated circuit device (e.g., a field-programmable gate array (FGPA)).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Learned parameter systems are becoming increasingly valuable in a number of technical fields due to their ability to improve performance on tasks without explicit programming. As an example, these systems may be used in natural language processing, image processing, computer vision, object recognition, bioinformatics, and the like, to recognize patterns and/or to classify data based on information learned from input data. In particular, learned parameter systems may employ machine learning techniques that use data received during a training or tuning phase to learn and/or adjust values of system parameters (e.g., weights). These parameters may be subsequently applied to data received during a use phase to determine an appropriate task response. For learned parameter systems that employ a subset of machine learning called deep learning (e.g., Deep Neural Networks), the parameters may be associated with connections between nodes (e.g., neurons) of an artificial neural network used by such systems.

As the complexity of learned parameter systems grows, the neural network architecture may also grow in complexity, resulting in a rapid increase of the number of connections between neurons and thus, the number of parameters employed. When these complex learned parameter systems are implemented via integrated circuits (e.g., FPGAs), the parameters may consume a significant amount of memory, bandwidth, and power resources of the integrated circuit system. Further, a bottleneck may occur during transfer of the parameters from the memory to the integrated circuit, thereby reducing the implementation efficiency of learned parameter systems on integrated circuits. Previous techniques used to reduce the number of parameters and/or to improve operation efficiency of the learned parameter system may include pruning and quantization. These techniques however, may force compromise between retraining, precision, accuracy, and available bandwidth. As a result, previous techniques may not improve operation efficiency of the learned parameter system in a manner that meets operation specifications.

### BRIEF DESCRIPTION OF THE DRAWINGS

Various aspects of this disclosure may be better understood upon reading the following detailed description and upon reference to the drawings in which:

FIG. 1 is a schematic diagram of a learned parameter system, in accordance with an embodiment of the present disclosure;

FIG. 2 is a block diagram of a data processing system that may use an integrated circuit to implement the learned parameter system of FIG. 1, in accordance with an embodiment of the present disclosure;

FIG. 3 is a block diagram of a design workstation that may be used to design the learned parameter system of FIG. 1, in accordance with an embodiment of the present disclosure;

FIG. 4 is a block diagram of components in the data processing system of FIG. 2 including a programmable integrated circuit used to implement the learned parameter system of FIG. 1, in accordance with an embodiment of the present disclosure;

FIG. 5 is a block diagram of components in the data processing system of FIG. 2 that implement compressed system parameters associated with the learned parameter system of FIG. 1, in accordance with an embodiment of the present disclosure;

FIG. 6 is a flow diagram of a process used to improve operation efficiency of the learned parameter system of FIG. 1, in accordance with an embodiment of the present disclosure;

FIG. 7 is a flow diagram of a process used to compress the system parameters of the learned parameter system of FIG. 1, in accordance with an embodiment of the present disclosure;

FIG. 8 is a table illustrating compression efficiency of the system parameters using the compression process of FIG. 5, in accordance with an embodiment of the present disclosure; and

FIG. 9 is an example of a result generated using the compression process of FIG. 5, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

Generally, as complexity of learned parameter systems grows, the number of parameters (e.g., weights) employed by the learned parameter systems may also increase. When these systems are implemented using a integrated circuit, the parameters may consume a significant amount of resources, reducing operational efficiency of the integrated circuit and/or performance of the learned parameter system. Accordingly, and as further detailed below, embodiments of the present disclosure relate generally to improving implementation efficiency of learned parameter systems implemented via integrated circuits by efficiently compressing the parameters. In some embodiments, at least a portion of the parameters may be compressed using run-length encoding techniques. For example, a segment of parameters with similar, consecutive values may be compressed using run-length encoding to reduce the amount of storage consumed by the parameters. In additional or alternative embodiments, special cases (e.g., infinity and/or not-a-number (NaN)) of the Institute of Electrical and Electronics Engineers Standard for Floating-Point Arithmetic (IEEE 754) may be used to secure and further reduce the size of a result generated by the run-length encoding.

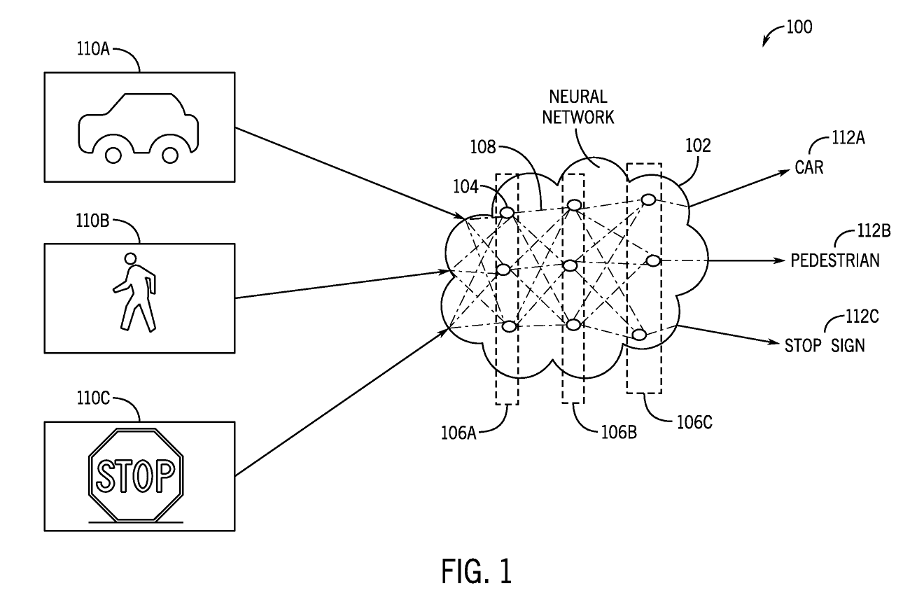

With the foregoing in mind, FIG. 1 is a learned parameter system 100 that may employ an artificial neural network architecture 102, in accordance with an embodiment of the present disclosure. As previously mentioned, learned parameter systems 100 may be used in a number of technical fields for a variety of applications, such as language processing, image processing, computer vision, and object recognition. As shown, the learned parameter system 100 may be a Deep Neural Network (DNN) that employs the neural network architecture 102 to facilitate learning by the system 100. In particular, the neural network architecture 102 may include a number of nodes 104 (e.g., neurons) that are arranged in layers (e.g., layers 106A, 106B, and 106C, collectively 106). The nodes 104 may receive an input and compute an output based on the input data and the respective parameters. Further, arranging the nodes 104 in layers 106 may improve granularity and enable recognition of sophisticated data patterns as each layer (e.g., 106C) builds on the information communicated by a preceding layer (e.g., 106B). The nodes 104 of a layer 106 may communicate with one or more nodes 104 of another layer 106 via connections 108 formed between the nodes 104 to generate an appropriate output based on an input. Although only three layers 106A, 106B, and 106C are shown in FIG. 1, it should be understood that an actual implementation may contain many more layers, in some cases reaching 100 layers or more. Moreover, as the number of layers 106 and nodes 104 increases, the greater the system resources that may be used.

Briefly, the neural network 102 may first undergo training (e.g., forming and/or weighting the connections 108) prior to becoming fully functional. During the training or tuning phase, the neural network 102 may receive training inputs that are used by the learned parameter system 100 to learn and/or adjust the weight(s) for each connection 108. As an example, during the training phase, a user may provide the learned parameter system 100 with feedback on whether the system 100 correctly generated an output based on the received trained inputs. The learned parameter system 100 may adjust the parameters of certain connections 108 according to the feedback, such that the learned parameter system 100 is more likely to generate the correct output. Once the neural network 102 has been trained, the learned parameter system 100 may apply the parameters to inputs received during a use-phase to generate an appropriate output response. Different sets of parameters may be employed based on the task, such that the appropriate model is used by the learned parameter system 100.

As an example, the learned parameter system 100 may be trained to identify objects based on image inputs. The neural network 102 may be configured with parameters determined for the task of identifying cars. During the use-phase, the neural network 102 may receive an input (e.g., 110A) at the input layer 106A. Each node 104 of the input layer 106A may receive the entire input (e.g., 110A) or a portion of the input (e.g., 110A) and, in the instances where the input layer 106A nodes 104 are passive, may duplicate the input at their output. The nodes 104 of the input layer 106A may then transmit their outputs to each of the nodes 104 of the next layer, such as a hidden layer 106B. The nodes 104 of the hidden layer 106B may be active nodes, which act as computation centers to generate an educated output based on the input. For example, a node 104 of the hidden layer 106B may amplify or dampen the significance of each of the inputs it receives from the previous layer 106A based on the weight(s) assigned to each connection 108 between this node 104 and nodes 104 of the previous layer 106A. That is, each node 104 of the hidden layer 106B may examine certain attributes (e.g., color, size, shape, motion) of the input 110A and generate a guess based on the weighting of the attributes.

The weighted inputs to the node 104 may be summed together, passed through a respective activation function that determines to what extent the summation will propagate down the neural network 102, and then potentially transmitted by the nodes 104 of a following layer (e.g., output layer 106C). Each node 104 of the output layer 106C may further apply parameters to the input received by the hidden layer 106B, sum the weighted inputs, and output those results. For example, the neural network 102 may generate an output that classifies the input 110A as a car 112A. The learned parameter system 100 may additionally be configured with parameters associated with the task of identifying a pedestrian and/or a stop sign. After the appropriate configuration, the neural network 102 may receive further inputs (e.g., 110B and/or 110C, respectively), and may classify the inputs appropriately (e.g., outputs 112B and/or 112C, respectively).

It should be appreciated that, while the neural network is shown to receive a certain number of inputs 110A-110C and include a certain number of nodes 104, layers 106A, 106B, and 106C, and/or connections 108, the learned parameter system 100 may receive a greater or fewer amount of inputs 110A-110C than shown and may include any number of nodes 104, layers 106A, 106B, and 106C, and/or connections 108. Further, references to training/tuning phases should be understood to include other suitable phases that adjust the parameter values to become more suitable for performing a desired function. For example, such phases may include retraining phases, fine-tuning phases, search phases, exploring phases, or the like. It should also be understood that while the present disclosure uses Deep Neural Networks as an applicable example of a learned parameter system 100, the use of the Deep Neural Network as an example here is meant to be non-limiting. Indeed, the present disclosure may apply to any suitable learned parameter system (e.g., Convolution Neural Networks, Neuromorphic systems, Spiking Networks, Deep Learning Systems, and the like).

To improve the learned parameter system's 100 ability to recognize patterns from the input data, the learned parameter system 100 may use a greater number of layers 106, such as hundreds or thousands of layers 106 with hundreds or thousands of connections 108. The number of layers 106 may allow for greater sophistication in classifying input data as each successive layer 106 builds off the feature of the preceding layers 106. Thus, as the complexity of such learned parameter systems 100 grows, the number of connections 108 and corresponding parameters may rapidly increase. Such learned parameter systems 100 may be implemented on integrated circuits.

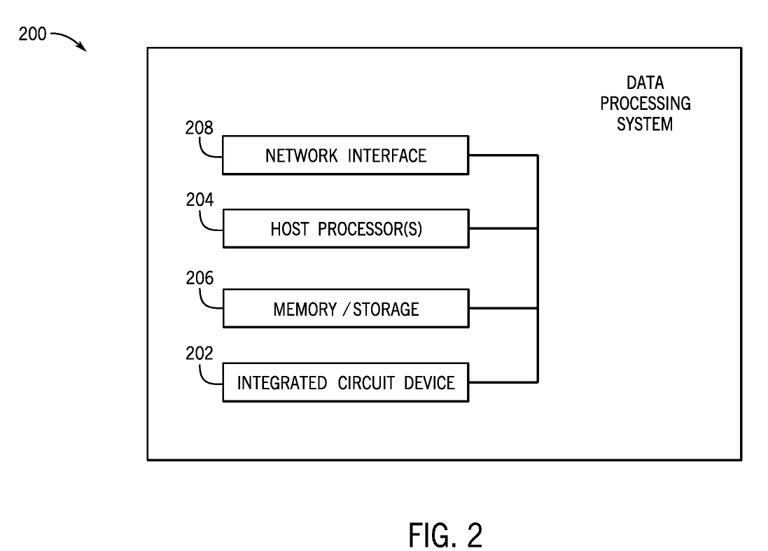

As such, FIG. 2 is a block diagram of a data processing system 200 including an integrated circuit device 202 that may implement the learned parameter system 100, according to an embodiment of the present disclosure. The data processing system 200 may include more or fewer components (e.g., electronic display, user interface structures, application specific integrated circuits (ASICs)) than shown. The data processing system 200 may include one or more host processors 204 may include any suitable processor, such as an INTEL® Xeon® processor or a reduced-instruction processor (e.g., a reduced instruction set computer (RISC), an Advanced RISC Machine (ARM) processor) that may manage a data processing request for the data processing system 200 (e.g., to perform machine learning, video processing, voice recognition, image recognition, data compression, database search ranking, bioinformatics, network security pattern identification, spatial navigation, or the like).

The host processor(s) 204 may communicate with the memory and/or storage circuitry 206, which may be a tangible, non-transitory, machine-readable-medium, such as random-access memory (RAM), read-only memory (ROM), one or more hard drives, flash memory, or any other suitable optical, magnetic or solid-state storage medium. The memory and/or storage circuitry 206 may hold data to be processed by the data processing system 200, such as processor-executable control software, configuration software, system parameters, configuration data, etc. The data processing system 200 may also include a network interface 208 that allows the data processing system 200 to communicate with other electronic devices. In some embodiments, the data processing system 200 may be part of a data center that processes a variety of different requests. For instance, the data processing system 200 may receive a data processing request via the network interface 208 to perform machine learning, video processing, voice recognition, image recognition, data compression, database search ranking, bioinformatics, network security pattern identification, spatial navigation, or some other specialized task. The data processing system 200 may further include the integrated circuit device 202 that performs implementation of data processing requests. For example, the integrated circuit device 202 may implement the learned parameter system 100 once the integrated circuit device 202 has been configured to operate as a neural network 102.

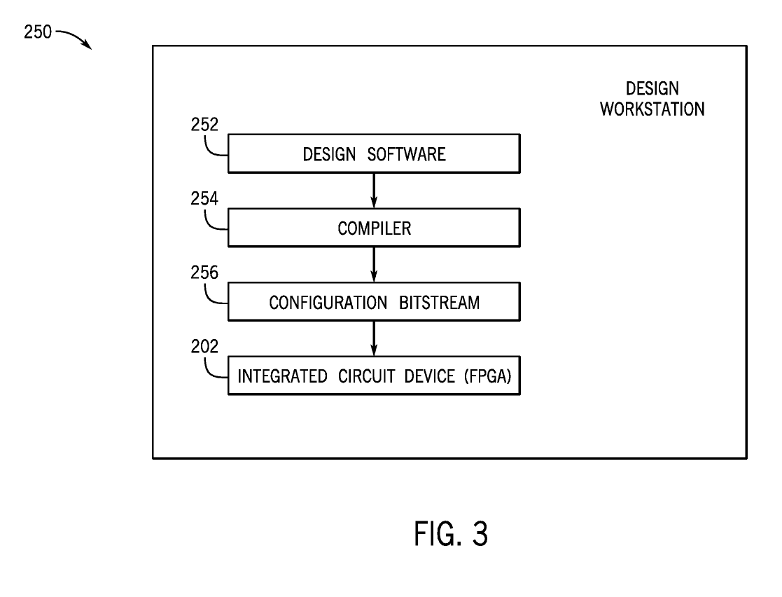

A designer may use a design workstation 250 to develop a design that may configure the integrated circuit device 202 in a manner that enables implementation, for example, of the learned parameter system 100 as shown in FIG. 3, in accordance with an embodiment of the present disclosure. In some embodiments, the designer may use design software 252 (e.g., Intel® Quartus® by INTEL CORPORATION) to generate a design that may be used to program (e.g., configure) the integrated circuit device 202. For example, a designer may program the integrated circuit device 202 to implement a specific functionality, such as implementing a trained Deep Neural Network (DNN). The integrated circuit device 202 may be a programmable integrated circuit, such as a field-programmable gate array (FPGA) that includes a programmable logic fabric of programmable logic units.

As such, the design software 252 may use a compiler 254 to generate a low-level circuit-design configuration for the integrated circuit device 202. That is, the compiler 254 may provide machine-readable instructions representative of the designer-specified functionality to the integrated circuit device 202, for example, in the form of a configuration bitstream 256. The configuration bitstream may be transmitted via direct memory access (DMA) communication or peripheral component interconnect express (PCIe) communications 306. The host processor(s) 204 may coordinate the loading of the bitstream 256 onto the integrated circuit device 202 and subsequent programming of the programmable logic fabric. For example, the host processor(s) 204 may permit the loading of the bitstream corresponding to a Deep Neural Network topology onto the integrated circuit device 202.

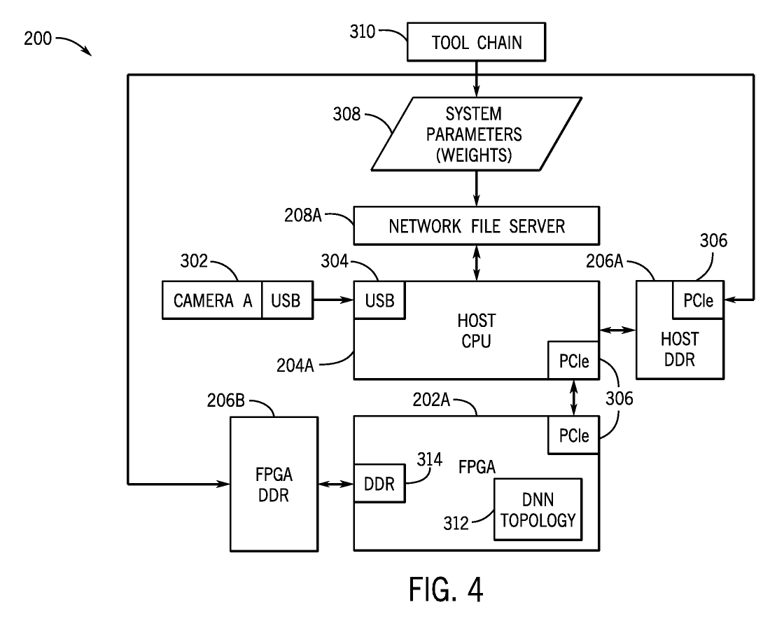

FIG. 4 further illustrates components of the data processing system 200 used to implement the learned parameter system 100, in accordance with an embodiment of the present disclosure. As shown, the learned parameter system 100 may be a Deep Neural Network implemented on a programmable integrated circuit, such as an FPGA 202A. In some embodiments, the FPGA 202A may be an FPGA-based hardware accelerator that performs certain functions (e.g., implementing the learned parameter system 100) more efficiently than possible by a host processor 204. As such, to implement the trained Deep Neural Network, the FPGA 202A may be configured according to a Deep Neural Network topology, as mentioned above.

The FPGA 202A may be coupled to a host processor 204 (e.g., host central processing unit (CPU) 204A) that communicates with the network interface 208 (e.g., network file server 208A). The network file server 208A may receive parameters 308 from a tool chain 310 that uses framework to train the learned parameter system 100 for one or more tasks. For example, OpenVINO® by INTEL CORPORATION may use TensorFlow® and/or Caffee® frameworks to train the predictive model of the learned parameter system 100 and to generate parameters 308 for the trained system 100. The network file server 208A may store the parameters 308 for a period of time and transfer the parameters 308 to the host CPU 204A, for example, before or after configuration of the FPGA 202A with the Deep Neural Network topology.

The host CPU 204A may store the parameters 308 in memory associated with the host CPU 204A, such as host double data rate (DDR) memory 206A. The host DDR memory 206A may subsequently transfer the parameters 308 to memory associated with the FPGA 202A, such as FPGA DDR memory 206B. The FPGA DDR memory 206B may be separate from, but communicatively coupled to the FPGA 202A using a DDR communication module 314 that facilitates communication between the FPGA DDR memory 206B and the FPGA 202A according to, for example, the PCIe bus standard. Upon receiving an indication from the host CPU 204A, the parameters 308 may be transferred from the FPGA DDR memory 206B to the FPGA 202A using the DDR communication module 314. In some embodiments, the parameters 308 may be transferred directly from the host CPU 204A to the FPGA 202A using PCIe 306, with or without temporary storage in the host DDR 206A and/or FPGA DDR 206B.

The parameters 308 may be transferred to a portion 312 of the FPGA 202A programmed to implement the Deep Neural Network architecture. These parameters 308 may further configure the Deep Neural Network architecture to analyze input for a task associated with the set of parameters 308 (e.g., parameters associated with identifying a car). The input may be received by the host CPU 204A via input/output (I/O) communication. For example, a camera 302 may transfer images for processing (e.g., classification) to the host CPU 204A via a USB port 304. The input data then be transferred to the FPGA 202A or FPGA DDR 206B from the host CPU 304, such that the data may be temporarily stored outside of the Deep Neural Network topology 312 until the learned parameter system 100 is ready to receive input data. Once the Deep Neural Network 312 generates the output based on the input data, the output may be stored in the FPGA DDR 206B and subsequently in the host DDR 206A. It should be appreciated that the components 200 may communicate with a different combination of components than shown and/or may be implemented in a different manner than described. For example, the FGPA DDR 206B may not be separated from the host DDR 206A and output data may be transmitted directly to the host CPU 204A.

As mentioned above, the Deep Neural Network topology 312 may include multiple layers 108, each with multiple computation nodes 104. For such complex learned parameter systems 100, the number of parameters 308 used during implementation of the Deep Neural Network topology 312 may consume a significant amount of resources, such as storage in the FPGA memory 206B, power, and/or bandwidth during transfer of the parameters 308 to the FPGA 202A, for example, from the FPGA DDR 206B, the host CPU 204A, and/or the host DDR 206. Consumption of a significant amount of resources may lead to a bottleneck, overwriting of data, reduction of performance speed, and/or reduction in implementation efficiency of learned parameter systems on the FPGA 202A.

In some embodiments, the parameters 308 of the learned parameter system 100 may be additionally or alternatively compressed by taking advantage of runs (e.g., sequence of consecutive data elements) of similar parameter values. In particular, Deep Neural Networks may have runs of parameter values that are zeros, for example, when the parameters act as filters for convolution-based Deep Neural Networks or when the activation functions are not active for every node 104. Non-zero values may be distributed amongst the runs of zero parameter values. Additionally or alternatively, Deep Neural Networks may assign a value of zero to many parameters to avoid overfitting, which may occur when the learned parameter system 100 effectively memorizes a dataset, such that the system 100 may not be able to recognize patterns that deviate from the input data used in training. In some instances, the runs of similar parameter values may be of non-zero values.

To compress the parameters 308 stored in floating-point format, in some embodiments, runs of similar parameter values may be compressed using run-length encoding (RLE), which reduces a run into a value indicating the run length and a value indicating the run (e.g., parameter type 308). The run lengths may be compared to a threshold to determine whether to run-length encode the run. The threshold, for example, may be determined based on memory storage constraints, bandwidth constraints, and the like. In some cases, using run-length encoding may increase resource consumption and/or reduce performance of the learned parameter system 100 and the data processing system 200 due to the separate storage of the run length and the run. That is, the separate storage of the run length and the run may increase the amount of data to be stored and/or transferred as compared to the original sequence of data.

As such, in some embodiments, special cases (e.g., infinity and/or not-a-number NaN)) of the Institute of Electrical and Electronics Engineers Standard for Floating-Point Arithmetic (IEEE 754) may be used in combination with the run-length encoding to efficiently compress the parameters 308. For example, only the compressed runs of the run-length encoding may be tagged using the special cases since the special cases do not translate into numerical values in floating point calculations. The special cases may be used to hide the run size and/or to indicate to the FPGA 202A to enter different processing modes, for example, to decode and decompress the IEEE 754 run-length encoded runs. Further, in some embodiments, the IEEE 754 run-length encoding may be applied for other floating-point formats, such as Big Float.

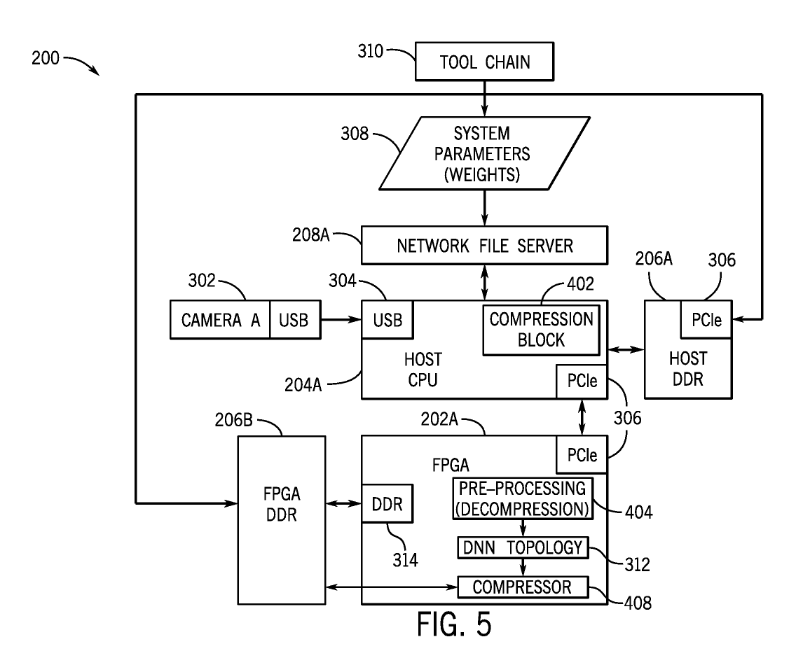

FIG. 5 illustrates components of the data processing system 200 that may be used to compress parameters 308 and implement the compressed parameters 308 with the learned parameter system 100, in accordance with an embodiment of the present disclosure. The data processing system 200 may operate in a manner similar to that described above. The data processing system 200 however, may implement the IEEE 745 run-length encoded parameters 308. In particular, the parameters 308 may be received by a compression block 402 of the host CPU 204A, and the compression block 402 may compress the parameters 308 in accordance with the IEEE 754 run-length encoding.

The parameters 308 may be transferred to a pre-processing block 404 of the FPGA 202A via PCIe 306 or the DDR communication module 314 from either the host CPU 204A or the FPGA DDR 206B, respectively. Because the special cases are never parameter values, the special cases may act as escape characters that signal the pre-processing block 404 to enter a decoding and decompressing mode as the parameters 308 are received. As such, the pre-processing block 404 may act as an in-line decoder that decodes encoded run lengths and decompresses the compressed parameters 308. Upon decompression of the parameters 308, the parameters 308 may be transmitted to the Deep Neural Network topology 312 and used to classify input data. In some embodiments, the parameters 308 may be compressed by the tool chain 310 in accordance with IEEE 754 run-length encoding. In such cases, the parameters 308 may be transferred to the FPGA 202A without further compression by the host CPU 204A.

Upon processing the input data using the decompressed parameters 308, the Deep Neural Network topology 312 may output the results to a compressor 408. The compressor 408 may use IEEE 754 run-length encoding to encode the results prior to transmitting and storing the results in memory, such as FPGA DDR memory 206B and/or Host DDR memory 206A. In some embodiments, the results may be encoded in real-time as they are generated. Further, the compressor 408 may encode or re-encode the parameters 308 in the instances where the value of the parameters 308 were adjusted during a run of the Deep Neural Network topology 312. It should be appreciated that IEEE 754 run-length encoding may also be used to encode input data received, for example, from the camera 302, or any other data used by the data processing system 200.

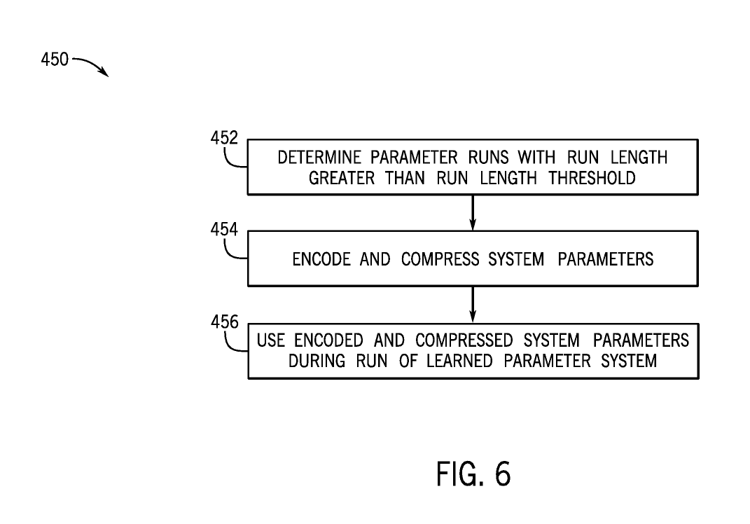

To summarize, FIG. 6 illustrates a process 450 for improved operation efficiency of the learned parameter system of FIG. 1, in accordance with an embodiment of the present disclosure. While the process 450 is described in a specific sequence, it should be understood that the present disclosure contemplates that the described process 450 may be performed in different sequences than the sequence illustrated, and certain portions of the process 450 may be skipped or not performed altogether. The process 450 may be performed by any suitable device or combination of devices that may generate or receive the parameters 308. In some embodiments, at least some portions of the process 450 may be implemented by the host processor 204A. In alternative or additional embodiments, at least some portions of the process 450 may be implemented by any other suitable components or control logic, such as the tool chain 310, the compiler 254, a processor internal to the integrated circuit device 202, and the like.

The process 450 may begin with the host CPU 204A or a tool chain 310 determining runs within the parameter sequence that have run lengths greater than a run length threshold (process block 452). The host CPU 204A or a tool chain 310 may then encode and compress the system parameters 308, for example, using run-length encoding and IEEE 754 special cases (process block 454). The integrated circuit device 202, upon indication by the host CPU 204A, may use the encoded and compressed system parameters 308 during a run of the learned parameter system 100 (process block 456). For example, the integrated circuit device 202 may multiply input data with a decoded and decompressed version of the system parameters 308.

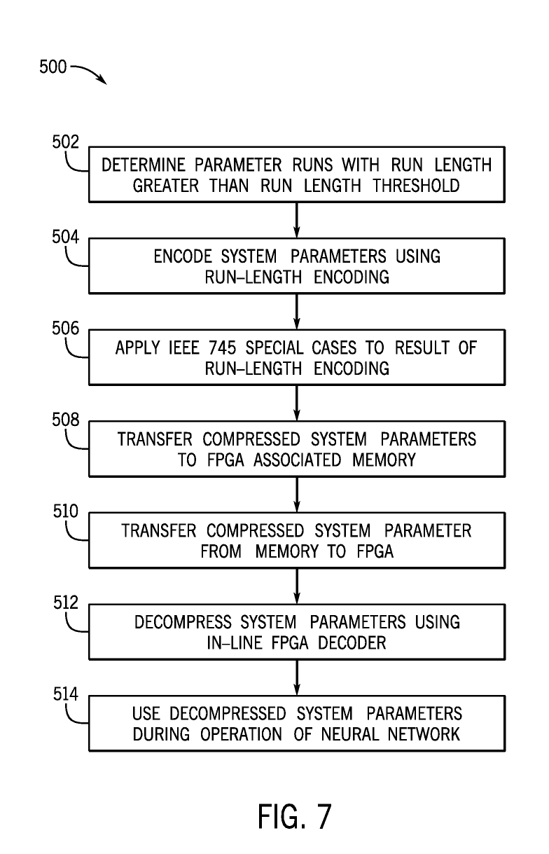

In particular, FIG. 7 further illustrates a process 500 for compressing parameters 308 of the learned parameter system 100 and for implementing the compressing parameters 308 via an integrated circuit 202, in accordance with an embodiment of the present disclosure. While the process 500 is described in a specific sequence, it should be understood that the present disclosure contemplates that the described process 500 may be performed in different sequences than the sequence illustrated, and certain portions of the process 500 may be skipped or not performed altogether. The process 500 may be performed by any suitable device or combination of devices that may generate or receive the parameters 308. In some embodiments, at least some portions of the process 500 may be implemented by the host processor 204A. In alternative or additional embodiments, at least some portions of the process 500 may be implemented by any other suitable components or control logic, such as the tool chain 310, the compiler 254, a processor internal to the integrated circuit device 202, and the like.

The process 500 may begin with the host CPU 204A or a tool chain 310 determining runs within the parameter sequence that have run lengths greater than a run length threshold (process block 502). The host CPU 204A or a tool chain 310 may encode runs of the parameter sequence greater than the threshold using run-length encoding (process block 504). Special cases of IEEE 754 may be applied to the result of the run-length encoding, such that runs compressed by the run-length encoding are tagged with non-numerical values (e.g., infinity and/or NaN) (process block 506). The host CPU 204A may indicate components of the data processing system 200 to transfer the compressed system parameters 308 to memory associated with the FPGA 202A, such as FPGA DDR 206B (process block 506). Further, the host CPU 204A may indicate the transfer of compressed system parameters 308 from the memory 206B to the FPGA 202A (process block 510). The host CPU 204A or a processor internal to the FPGA 202A may signal the pre-processing block 404 to decompress the system parameters 203 as received (process block 512). Upon decompression of the parameters 308, the parameters 308 may be transferred to a neural network topology 312 and used during operations of the neural network 312 to classify input data (process block 514).

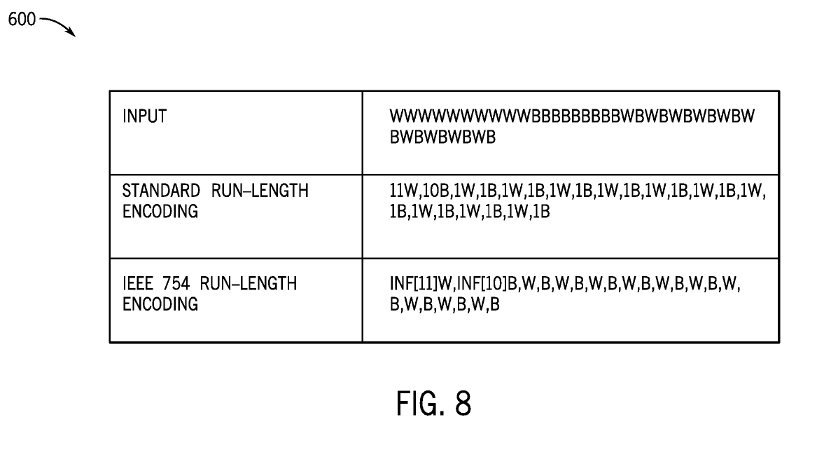

The table 600 of FIG. 8 compares compression efficiencies using IEEE 754 run-length encoding over standard run-length encoding, in accordance with an embodiment of the present disclosure. As shown, the table 600 makes use of a an easy to understand input that may or may not be representative of information included in a set of parameters 308. The input may include one or more runs of similar parameter values. Standard run-length encoding may designate a run value and run length for each run, even in instances where the runs are of 1 bit-length. As a result, each run may result in two values that are stored separately. In some cases where the runs are relatively short (e.g., 1-bit length), the standard run-length encoding may increase the data that will be stored, reducing system performance and implementation speeds.

Applying the compression techniques described here may also enhance security. This is because the run lengths of uncompressed parameters could be deciphered and used by parties for malicious intent. On the other hand, IEEE 754 run-length encoding may apply run-length encoding to runs that have a length greater than a specified run-length threshold, thereby ensuring compression of data stored. Further, special cases of IEEE 754, such as infinity and NaN, may be applied to the run-length information. This may allow for enhanced security of the run-length from malicious parties and/or may act as indicators to the FPGA 202A to decode and decompress the compressed parameters 308. As such, IEEE 754 run-length encoding may enhance security of the system parameters 308, reduce the consumption of memory bandwidth over 60%, and may further reduce consumption of power and memory storage.

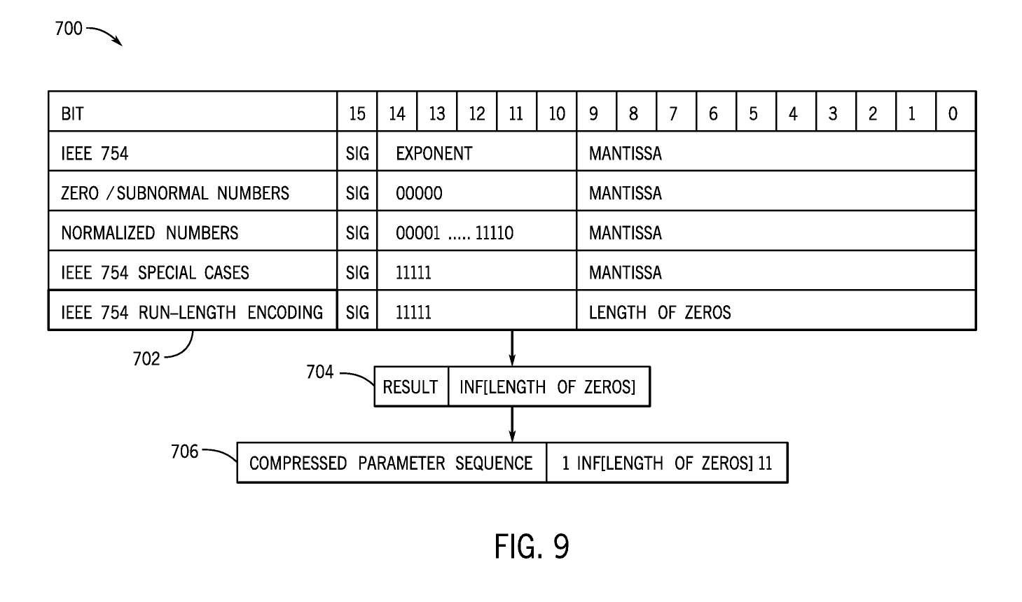

FIG. 9 details an example 700 of a sequence of parameters that is compressed using IEEE 754 run-length encoding, in accordance with an embodiment of the present disclosure. As shown, a sequence of parameters 308 may be stored in floating point format under IEEE 754, which divides the floating-point value into a sign field, exponent field, and mantissa field. In particular, the sign field may be a high bit value or a low bit value used to represents positive or negative numbers, respectively. Further, the exponent field may include information on the exponent of a floating-point number that has been normalized (e.g., number in scientific notation). The mantissa field may store to the precision bits of the floating-point number. Although shown at a 16-bit number in this example, the floating-point bit precision may be 8, 32, or 64 bits.

Zeros and/or subnormal numbers (e.g., non-zero numbers with magnitude smaller than that of the smallest normal number) may be stored as all zero bits in the sign, exponent, and mantissa fields. The exponent field for normalized numbers under standard IEEE 754 may include the exponent value of the scientific notation while the mantissa may include the significant digits of the floating-point number. IEEE special cases may be applied to the standard IEEE 754 format to tag the floating-point number. For example, the exponent field may store “11111” which may translate to NaN. Alternatively, the exponent field may be populated with “11111” to designate positive infinity.

In some embodiments, the IEEE 754 special cases may be applied to a run-length encoding result to further compress the result. As shown, the IEEE 754 run-length encoding 802 may be applied to a run of the parameter sequence that includes consecutive zeros. The exponent field may be designated with the special case to flag that the run has been encoded using IEEE 754 run-length encoding. The mantissa, rather than holding the number of significant digits in the floating-point number, may be modified to indicate the length of consecutive zeros in the run. The resulting compressed run 704 is shown in a format similar to that of table 600. When the run 704 is part of a sequence of parameter values, the run 704 may be included to generate a compressed parameter sequence 706. For example, the compressed parameter sequence 706 may include non-zero value (e.g., 1) parameter values associated with certain nodes 104 as well as runs 704 of zeros that are compressed using the IEEE 754 run-length encoding. It should be understood that the example 800 may be applicable to runs with any consecutive value, such as non-zero values, and to numbers in any floating-point format.

The present systems and methods relate to embodiments for improving implementation efficiency of learned parameter systems 100 implemented via integrated circuits 202 by efficiently compressing system parameters 308. The present embodiments may improve performance speed of the learned parameter system 100 and/or the data processing system 200. Further, the present embodiments may reduce consumption of resources, such as power, memory storage, available memory bandwidth, that are readily consumed by complex learned parameter systems 100. Furthermore, the embodiments may compress the parameters 308 without compromising on precision, accuracy, and system 100 retraining. Additionally, IEEE 754 run-length encoding may compress the parameters while further securing the parameters 308 from malicious parties due to the special cases hiding the size of the encoded run 704.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A method for implementing compressed parameters of a learned parameter system on an integrated circuit, comprising:
receiving, via a processor communicatively coupled to the integrated circuit, a sequence of parameters of the learned parameter system;
comparing, via the processor communicatively coupled to the integrated circuit, a length of a run of the sequence of parameters to a run-length threshold, wherein the run comprises a consecutive portion of parameters of the sequence of parameters that each have a value within a defined range;
in response to the run being greater than or equal to the run-length threshold, compressing, via the processor communicatively coupled to the integrated circuit, the parameters of the run using run-length encoding; and
storing, via the processor communicatively coupled to the integrated circuit, the parameters of the run into memory that is communicatively coupled to the integrated circuit in compressed form, wherein the integrated circuit is configured to retrieve the parameters of the run in compressed form, decode the parameters of the run, and use the parameters of the run in the learned parameter system.

2. The method of claim 1, wherein the learned parameter system comprises a neural network.

3. The method of claim 2, wherein the neural network comprises a Deep Neural Network, a Convolutional Neural Network, Neuromorphic systems, Spiking Networks, Deep Learning Systems, or any combination thereof.

4. The method of claim 1, wherein the defined range consists of a value of zero.

5. The method of claim 1, wherein the defined range comprises values less than a smallest normal number represented in a particular floating-point format.

6. The method of claim 5, wherein the defined range consists of the values less than the smallest normal number represented in the particular floating-point format.

7. The method of claim 1, comprising additionally compressing, via the processor communicatively coupled to the integrated circuit, the parameters of the run at least in part by applying special cases as defined by a specification.

8. The method of claim 7, wherein the specification comprises Institute of Electrical and Electronics Engineers Standard for Floating-Point Arithmetic (IEEE 754), and wherein the special cases comprise infinity or not-a number (NaN), or a combination thereof.

9. The method of claim 7, wherein applying the special cases to the parameters of the run comprises tagging a length of the run.

10. The method of claim 1, wherein the run-length threshold varies based at least in part on bandwidth available to the integrated circuit, storage available to memory associated with the integrated circuit, or a combination thereof.

11. The method of claim 1, comprising configuring, via the processor communicatively coupled to the integrated circuit, the integrated circuit with a circuit design comprising a topology of the learned parameter system.

12. The method of claim 11, wherein the integrated circuit comprises field programmable gate array (FPGA) circuitry, wherein configuring the integrated circuit comprises configuring the FPGA circuitry.

13. An integrated circuit system comprising:
memory storing compressed parameters of a learned parameter system, wherein the parameters are compressed according to run-length encoding;
decoding circuitry configured to decode the compressed parameters to obtain the parameters of the learned parameter system; and
circuitry configured as a topology of the learned parameter system, wherein the circuitry is configured to operate on input data based at least in part on the topology of the learned parameter system and the parameters of the learned parameter system.

14. The integrated circuit system of claim 13, wherein the parameters comprise a consecutive sequence of parameters that each have a value within a defined range, wherein a length of the consecutive sequence of parameters is greater than or equal to a run-length threshold.

15. The integrated circuit system of claim 14, wherein the parameters are additionally compressed at least in part by applying special cases as defined by a specification, wherein the specification comprises Institute of Electrical and Electronics Engineers Standard for Floating-Point Arithmetic (IEEE 754), and wherein the special cases comprise infinity or not-a number (NaN), or a combination thereof.

16. The integrated circuit system of claim 13, comprising compression circuitry configured to perform in-line encoding and compression of results generated by the learned parameter system, the parameters used by the learned parameter system, or a combination thereof.

17. The integrated circuit system of claim 13, wherein the decoding circuitry performs in-line decoding and decompression of the compressed parameters.

18. A computer-readable medium storing instructions for implementing compressed parameters of a learned parameter system on a programmable logic device, comprising instructions to cause a processor communicatively coupled to the programmable logic device to:
receive a sequence of parameters of the learned parameter system;
determining of a portion of the sequence of parameters with a length greater than or equal to a run-length threshold, wherein the portion comprises consecutive parameters of the sequence of parameters each with a value within a defined range;
compressing, in response to determining the portion, parameters of the portion using run-length encoding and special cases as defined by a specification; and
storing the parameters of the portion in a compressed form into memory communicatively coupled to the programmable logic device.

19. The computer-readable medium of claim 18, wherein the specification comprises Institute of Electrical and Electronics Engineers Standard for Floating-Point Arithmetic (IEEE 754), and wherein the special cases comprise infinity or not-a number (NaN), or a combination thereof.

20. The computer-readable medium of claim 18, comprising:
configuring the programmable logic device with a circuit design comprising a topology of the learned parameter system;
applying the stored parameters of the portion to received data during operation of the learned parameter system to generate a result; and
compressing the result in-real time using the specification.
